(19) United States
(12) Patent Application Publication
(10) Pub. No.: US 2025/0233389 A1
(43) Pub. Date: Jul. 17, 2025

(54) SURFACE EMITTING LASER, METHOD FOR FABRICATING SURFACE EMITTING LASER

(71) Applicant: SANOH INDUSTRIAL CO., LTD., Tokyo (JP)

(72) Inventor: Srinivas Gandrothula, Koga-shi, Ibaraki (JP)

(21) Appl. No.: 18/852,550

(22) PCT Filed: Mar. 31, 2022
(86) PCT No.: PCT/JP2022/016925

§ 371 Date: Sep. 30, 2024

(51) Int. Cl. H01S 5/183; H01S 5/026

(52) U.S. Cl. CPC H01S 5/18369; H01S 5/026

(57) ABSTRACT

A vertical cavity surface emitting laser (VCSEL) includes a distributed Bragg reflector (DBR) including a first dielectric layer and a second dielectric layer alternately arranged in a first axial direction; and a semiconductor section including a p-type III nitride region, a III nitride region, and a Ill nitride active region between the p-type Ill nitride region and the III nitride region, the p-type III nitride region, the Ill nitride active region, and the Ill nitride region being arranged in the first axial direction, the Ill nitride region including an n-type III nitride region. The semiconductor section includes a monolithic grating having a periodic one-dimensional pattern. The monolithic grating, the Ill nitride active region, and the distributed Bragg reflector are arranged in the first axial direction to form an optical cavity. The periodic one-dimensional pattern extends in a second axial direction that intersects the first axial direction.

### TECHNICAL FIELD

This invention relates to a surface emitting laser, and a method for fabricating a surface emitting laser.

### BACKGROUND ART

Surface emitting lasers are known as vertical cavity surface emitting lasers (VCSELs). A VCSEL comprises a semiconductor active region disposed between an n-side semiconductor region and a p-side semiconductor region, and two distributed Bragg reflectors, DBRs, which act as high reflective mirrors. The semiconductor active region is disposed between the two DBRs to form an optical cavity. The n-side and p-side regions inject respective carriers, i.e., electron and hole, to the active region, and these carriers are recombined in the active region to generate light. Light thus generated is reflected many times by the DBRs to travel in the optical cavity, thereby lasing. The VCSEL provides one of the DBRs with a less reflectance mirror, which is used to emit the laser beam.

### PRIOR ART DOCUMENT

### Non Patent Literature

NPL 1. Appl. Phys. Lett. 92, 141102 (2008)
NPL 2. Apply. Phys. Express, 12, 036504 (2019)
NPL 3. Appl. Phys. Lett. 105, 031111 (2014)
NPL 4. J. Vac. Sci. Technol. B 33, 050603 (2015)
NPL 5. Appl. Phys. Express 12, 044004 (2019)
NPL 6. Sci. Rep. 8, 10350 (2018)
NPL 7. Semicond. Sci. Technol. 26, 014017 (2010)
NPL 8. IEEE Signal Process. Mag. 37, 50-61 (2020)
NPL 9. IEICE Trans. Electron. E92-C, 194 (2009)
NPL 10. Phys. Stat. Soli, 215, 1700513 (2018)
NPL 11. Appl. Phys. Lett. 75, 1515 (1999)
NPL 12. Soc. Inf. Disp. Int. Symp. Dig. Tech. 44, 832 (2013)
NPL 13. AIP Adv. 3, 072107 (2013)
NPL 14. Optics Letters, 41, 2608-2611 (2016)
NPL 15. Phys. Status Solidi A. 215, 1700513 (2018)
NPL 16. Opt. Express, 27,24717 (2019)
NPL 17. Appl. Phys. Express, 13, 041003 (2020)
NPL 18. Appl. Phys. Express, 14,031002 (2021)
NPL 19. Applied Phys. Lett. 119, 142103 (2021)
NPL 20. Crystals, 11 (12) 1563, (2021)

### SUMMARY OF INVENTION

### Technical Problem

The fabrication of the reflective mirrors, i.e., distributed Bragg reflectors, in VCSELs has been a quite challenge in the scientific community for decades, especially for group III-nitride material system. A III-nitride VCSEL is provided with the top-mirror and the bottom-mirror. III-nitride device layers are deposited on the substrate to form the semiconductor laminate of the n-side region, the active region, and the p-side region, and then the top-mirror can be formed as namely the p-side mirror on the semiconductor laminate, and includes alternating layers of different dielectric materials disposed on the device layers. The bottom-mirror has to be positioned to form the cavity with the top and bottom mirrors being located close to each other to allow the formation of the optical cavity, which results in the removal of the substrate. Another approach to form the bottom mirror without removing the substrate is to use epitaxial DBRs in Ref. (NPL1) or nanoporous DBRs in Ref. (NPL2). Still another approach to form the bottom mirror is to use dielectric DBRs in Ref. (NPL 3) or high-index contrast gratings in Ref. (NPL 4), which are formed by polishing the substrate all the way to the device layers or separating the substrate by laser lift-off. These approaches, however, show that the fabrication of the bottom mirror is still a bottleneck challenge, and each approach has several technical difficulties than advantages.

For example, the formation of the epitaxial DBR is complex and needs time consuming semiconductor deposition, and may prone to the degraded crystalline quality. The formation of the dielectric DBR needs removal of the substrate which uses complex chemical mechanical polishing (CMP). Using CMP in the removing process is again challenging, tedious, and difficult to control, and wastes expensive III nitride substrates.

Alternatively, curved mirror approaches in Refs. (NPL5) and (NPL6) use a significant portion of the substrate and involve polishing and etching of the semiconductor substrate to formulate the n-side DBR mirror. The curved DBR mirror is formed on the back side of the substrate, so that this structure of the VCSEL doesn't require the removal of substrates that leads to several disadvantages. Using the curved mirror provides the VCSEL with a long optical cavity.

Specifically, the substrate is first thinned in thickness to reduce absorption loss in the cavity, and thinning the substrate can be a difficult process to control and may damage the wafer because the substrate have to be thinned from an initial thickness of 300 to 400 micrometers to a target thickness of 10 to 30 micrometers to provide the VCSEL with the cavity.

Yet another approach is to provide III nitride based VCSELs with a monolithic high-index contrast grating as a reflective mirror. The fabrication of gratings used in visible wavelengths involves complexity, etching of the semiconductor material. In the long operating time, the device performance may be degraded to shorten the device lifetime.

Also, the existing method for fabricating a high-index contrast grating uses electron-beam (e-beam) lithography and etching, which may damage the device layers. Accordingly, this process needs additional protective layers to avoid damage to the active region and subsequent device layers.

Considering all these disadvantages, it is an object to provide a structure of a III nitride-based VCSEL and a method for fabricating a Ill nitride-based VCSEL. It is another object to provide a monolithic high-index contrast grating and a method for fabricating a high-index contrast grating monolithically using epitaxial lateral overgrowth (ELO). The ELO process and the ELO structure allow the semiconductor device layers to have high crystalline quality and can prevent the device layers from being directly subjected to the etching environment in the formation of gratings.

### Solution to Problem

One aspect of the present disclosure is a VCSEL, which includes a first distributed Bragg reflector (DBR) including a first dielectric layer and a second dielectric layer alternately arranged in a first axial direction; and a semiconductor section including a p-type Ill nitride region, a Ill nitride region, and a Ill nitride active region between the p-type III nitride region and the Ill nitride region, the p-type Ill nitride region, the III nitride active region, and the Ill nitride region being arranged in the first axial direction, the Ill nitride region including an n-type III nitride region, wherein the semiconductor section includes a monolithic grating having a periodic one-dimensional pattern, the monolithic grating, the III nitride active region, the distributed Bragg reflector are arranged in the first axial direction to form an optical cavity, and the periodic one-dimensional pattern extends in a second axial direction that intersects the first axial direction.

Another aspect of the present disclosure is a method for fabricating a VCSEL, and the method includes: forming a patterned epitaxial lateral overgrowth (ELO) mask on a face of a substrate including one of a Ill nitride substrate, a silicon substrate, a sapphire substrate, a GaN-on-Sapphire template, or a GaN-on-Silicon template, the patterned ELO mask including a grating pattern and an opening to the face of the substrate; growing a III nitride on the substrate using the patterned ELO mask to form a Ill nitride region that covers the grating pattern, the grating pattern being transferred to the III nitride region; growing a semiconductor laminate including an n-type Ill nitride region, a Ill nitride active region, and a p-type III nitride region; after growing the semiconductor laminate, growing a conductive layer; forming a distributed Bragg reflector (DBR) on the conductive layer to fabricate a product, the DBR including a first dielectric layer and a second dielectric layer alternately arranged; and removing the substrate from the product to expose the patterned ELO mask; wherein the grating pattern includes a periodic one-dimensional pattern that extends along the face of the substrate.

### Advantageous Effects of Invention

The above aspects can provide a structure of a Ill nitride-based VCSEL and a method for fabricating a Ill nitride-based VCSEL.

### BRIEF DESCRIPTION OF DRAWINGS

FIG. 1 is a schematic view showing a vertical cavity surface emitting laser (VCSEL) according to the present embodiment.

FIG. 2 is a flow chart showing major steps of method for fabricating a VCSEL according to the present embodiment.

FIGS. 3A, 3B, 3C and 3D show steps for fabricating the monolithic grating according to the present embodiment.

FIG. 4 is a plan view showing a patterned ELO mask that is formed by twice patterning.

FIGS. 5A, 5B, and 5C show major steps for fabricating the VCSEL according to the present embodiment.

FIGS. 6A, 6B, and 6C show major steps for fabricating the VCSEL according to the present embodiment.

FIGS. 7A, 7B, and 7C show major steps for fabricating the VCSEL according to the present embodiment.

FIGS. 8A, 8B, and 8C show major steps for fabricating the VCSEL according to the present embodiment.

FIGS. 9A and 9B show major steps for fabricating the VCSEL according to the present embodiment.

FIGS. 10A, 10B, and 10C show major steps for fabricating the VCSEL according to the present embodiment.

FIG. 11A is a plan view showing a VCSEL according to the present embodiment, and FIG. 11B is a cross sectional view, taken along I-I line shown in FIG. 11A.

FIG. 12A is a plan view showing a VCSEL according to the present embodiment, and FIG. 12B is a cross sectional view, taken along II-II line shown in FIG. 12A.

FIG. 13A is a plan view showing a VCSEL according to the present embodiment, and FIG. 13B is a cross sectional view, taken along III-III line shown in FIG. 13A.

FIG. 14A is a plan view showing a VCSEL according to the present embodiment, and FIG. 14B is a cross sectional view, taken along IV-IV line shown in FIG. 14A.

FIG. 15A is a plan view showing a VCSEL according to the present embodiment, and FIG. 15B is a cross sectional view, taken along V-V line shown in FIG. 15A.

### DESCRIPTION OF EMBODIMENTS

Teachings of the present invention can be readily understood by considering the following detailed description with reference to the accompanying drawings shown as examples. Referring to the accompanying drawings, a schematic view showing a vertical cavity surface emitting laser, a method for fabricating a vertical cavity surface emitting laser, a monolithic high-index contrast grating and a method for fabricating a high-index contrast grating monolithically using epitaxial lateral overgrowth according to the present disclosure will be described below. To facilitate understanding, identical reference numerals are used, where possible, to designate identical elements that are common to the figures.

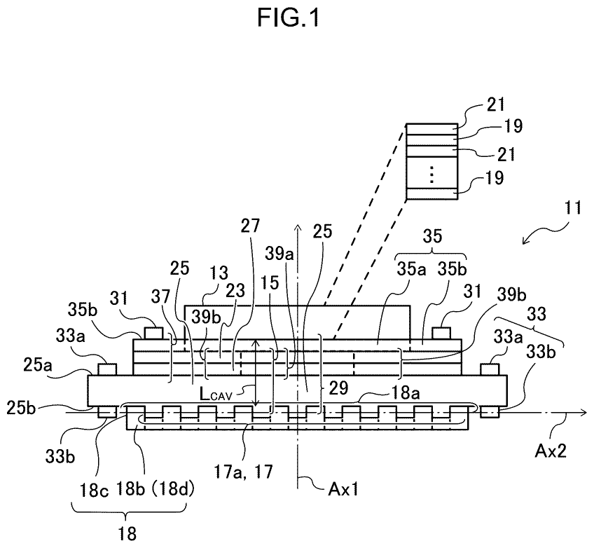

FIG. 1 is a schematic view showing a vertical cavity surface emitting laser (VCSEL) according to the present embodiment. A VCSEL 11 comprises a distributed Bragg reflector (DBR) 13, and a semiconductor section 15 including a monolithic grating 17. The DBR 13 includes first dielectric layers 19 and second dielectric layers 21 alternately arranged in a first axial direction Ax1, and the material of the first layers 19 is different from that of the second layers 21. The semiconductor section 15 excludes the substrate that was used to grow it. The VCSEL 11 may further comprise a dielectric layer 18 which can cover a part or all of the monolithic grating 17, and the dielectric layer 18 may extend along the surface structure of the monolithic grating 17 because it comes from a patterned ELO mask which is used in the growth process, which will be described below.

The semiconductor section 15 includes a p-type Ill nitride region 23, a Ill nitride region 25 including an n-type III nitride region, and a Ill nitride active region 27 between the p-type III-nitride region 23 and the n-type III nitride region of the III nitride region 25. The p-type III nitride region 23, the Ill-nitride active region 27, and the n-type III nitride region of the Ill nitride region 25 are arranged in the first axial direction Ax1. The monolithic grating 17 has a periodic one-dimensional pattern 17a. The monolithic grating 17, the semiconductor section 15, and the DBR 13 are arranged in the first axial direction Ax1 to form an optical cavity 29. The monolithic grating 17 is disposed along the face of the Ill nitride region 25, and the periodic one-dimensional pattern 17a extends in a second axial direction Ax2 that intersects the first axial direction Ax1.

The VCSEL 11 further includes an anode electrode 31 and a conductive layer 35. The conductive layer 35 has an inner portion 35a and an outer portion 35b which surrounds the inner portion 35a, and is disposed on the p-type Ill nitride region 23. The inner portion 35a is transparent to light from the III nitride active region 27, and can be disposed between the semiconductor section 15 and the DBR 13. The outer portion 35b is not covered with the DBR 13, which allows the anode electrode 31 to be in contact with the outer portion 35b. The conductive layer 35 connects the anode electrode 31 with the p-type III nitride region 23. The conductive layer 35 may include either a Ill nitride semiconductor, such as p-type GaN, or a conductive inorganic material, such as indium tin oxide (ITO), or both. In an example, the DBR 13 can be disposed in contact with the conductive layer 35. If needed, the semiconductor section 15 may further include a tunnel junction disposed between the p-type Ill nitride region 23 and the conductive layer 35, which has the n-type conductivity.

The VCSEL 11 includes a cathode electrode 33. The cathode electrode 33 is electrically connected with the n-type Ill nitride region of the III nitride region 25. As shown in FIG. 1, the cathode electrode 33 (33a and 33b) can be disposed in contact with either the front or back face of the n-type Ill nitride region of the Ill nitride region 25, or both.

Specifically, the cathode electrode 33 (33a and 33b) may be disposed in contact with either the front or back face of the n-type Ill nitride region of the Ill nitride region 25.

In the VCSEL 11 that provides the semiconductor section 15 with a mesa 37, the mesa 37 includes the p-type III nitride region 23, the III nitride active region 27 and a part of the n-type III nitride region of the III nitride region 25. The mesa 37 is located on the reminder of the n-type Ill nitride region of the Ill nitride region 25, and at the bottom of the mesa 37, the mesa 37 is surrounded by the n-type Ill nitride front face 25a of the Ill nitride region 25. The cathode electrode 33a may be disposed on the n-type Ill nitride front face 25a of the III nitride region 25.

In the VCSEL 11 that provides the monolithic grating 17 having a surrounding part which is not covered with the dielectric layer 18 to expose a part of the n-type Ill nitride back face 25b of the Ill nitride region 25, the cathode electrode 33b may be disposed on the n-type III nitride back face 25b, which is located outside the monolithic grating 17 and the dielectric layer 18.

The dielectric layer 18 may include a non-patterned portion 18b and a patterned portion 18c. The patterned portion 18c can cover the back face 25b of the n-type III nitride region 25, so that the patterned portion 18c is provided with a periodic one-dimensional pattern 18a that corresponds to the periodic one-dimensional pattern 17a. The non-patterned portion 18b can be replaced with another dielectric DBR laminate 18d, so that the monolithic grating 17 includes not only the periodic one-dimensional pattern 17a, which extends in the second axial direction Ax2, but also the other dielectric DBR laminate 18d, which includes two kind of dielectric layers alternately arranged in the first axial direction Ax1.

The cavity 29 has a total cavity length LCAV, which can be defined as a distance between the monolithic grating 17 and the DBR 13 in the present VCSEL 11, more than 1 micrometer. The total cavity length LCAV is not more than 30 micrometers because the VCSEL 11 does not include any part of the substrate that was used to grow the semiconductor section 15.

The semiconductor section 15 has a conductive aperture portion 39a and a less conductive portion 39b which surrounds the aperture conductive portion 39a. The aperture conductive portion 39a provides the VCSEL 11 with an electrical path from the anode electrode 31 to the cathode electrode 33. Carriers, such as electron and hole, flow through the electrical path, and are recombined in the Ill nitride active region 27 to generate light, which emits from one of the DBR 13 or the monolithic grating 17.

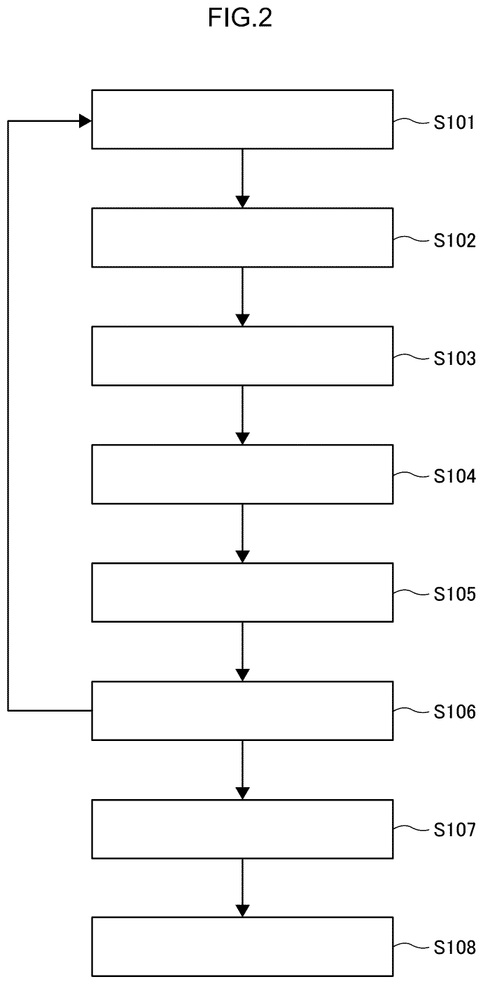

FIG. 2 is a flow chart showing major steps of a method for fabricating a VCSEL. Referring to FIG. 2, an outlined description will be given of an exemplary fabrication process according to the present embodiment. First, a substrate is prepared in S101. In S102, an epitaxial lateral overgrowth (ELO) mask is formed on the substrate, and is provided with a surface patterned for a periodic one-dimensional pattern 18a to produce a patterned ELO mask from the ELO mask. In S103, Ill nitride is deposited on the substrate and the patterned ELO mask. This deposition on the patterned ELO mask can transfer the patterned surface of the patterned ELO mask to the III nitride thus deposited. In S104, the Ill nitride thus deposited is polished to obtain a planer surface and adjust a cavity length of the VCSEL. On the planarized surface, a Ill nitride semiconductor laminate is grown in S105, and then a frontend processing is carried out to form an aperture structure, a DBR, and electrodes, thereby fabricating a product. In S106, the product is bonded to a supporting tool, and then the substrate is separated from the product, for example, by either cryogenic treatment or laser lift-off to obtain a device laminate bonded to the supporting tool. The substrate thus separated may be reclaimed. In S107, a backend processing is applied to the device laminate, and then in S108, the device laminate is separated into semiconductor device chips.

A detailed description will be given of an exemplary VCSEL according to the present embodiment below. In the following description, III nitride can be deposited by, for example, metal organic chemical vapor deposition (MOCVD).

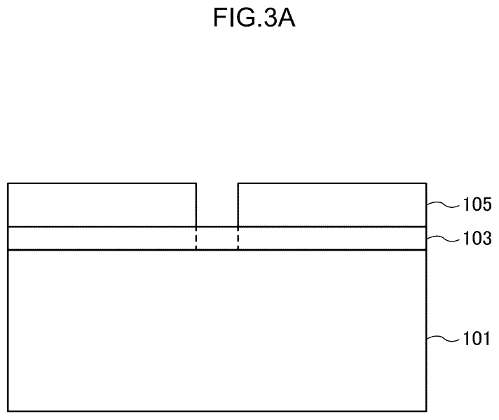

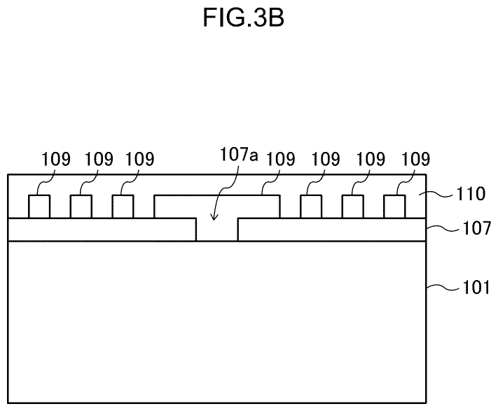

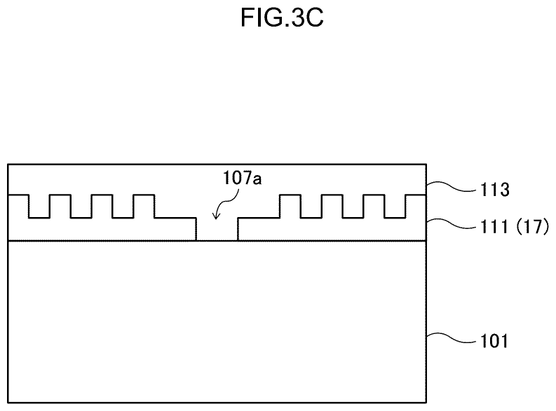

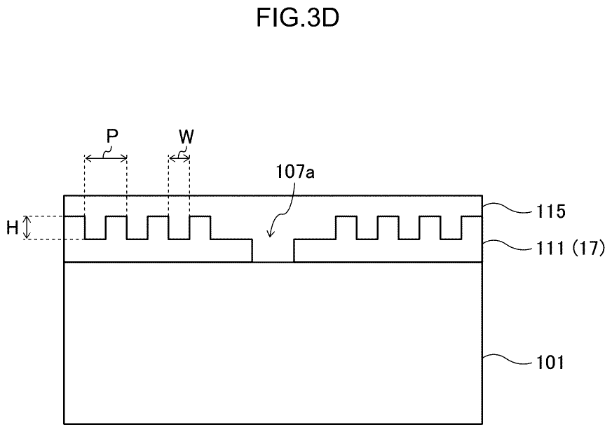

FIGS. 3A, 3B, 3C and 3D show steps for fabricating the monolithic grating 17. Referring to FIGS. 3A and 3B, a substrate 101 is prepared which can include one of a III nitride substrate, a GaN-on-Sapphire substrate, a GaN-on-Si substrate, a silicon substrate, a sapphire substrate, or other foreign substrate. The Ill nitride substrate may include gallium nitride-based material, such as gallium nitride (GaN). Before carrying out epitaxial lateral overgrowth (ELO), an ELO mask 103 is formed on a face of the substrate 101 by photo lithography and etching. The ELO mask 103 includes inorganic dielectric material, such as silicon oxide. Specifically, a layer of inorganic dielectric material is deposited on substrate 101, and then is patterned twice for not only the ELO but also the monolithic grating 17.

Specifically, as shown in FIGS. 3A to 3C, a photo lithographic mask 105, such as resist, is first formed on the inorganic dielectric layer 103, and the inorganic dielectric layer 103 is etched with the resist mask 105 to form an ELO mask 107 having an ELO pattern, which includes openings 107a to the substrate 101. After removing the photo lithographic mask 105, another photo lithographic mask 109, such as resist, is formed on the ELO mask 107, and then a dielectric layer 110 is deposited over the mask 109. In order to provide the ELO mask 107 with a one-dimensional pattern, the dielectric layer 110 is etched without any mask so as to expose the top of the mask 109, and then removing the resist mask 109 produces a patterned ELO mask 111, which has a pattern 18a for the monolithic grating 17.

In the present embodiment, the first patterning is to form the ELO pattern, and the second patterning is to form the pattern 18a for the monolithic grating 17. If needed, the second patterning may be first carried out prior to the first patterning.

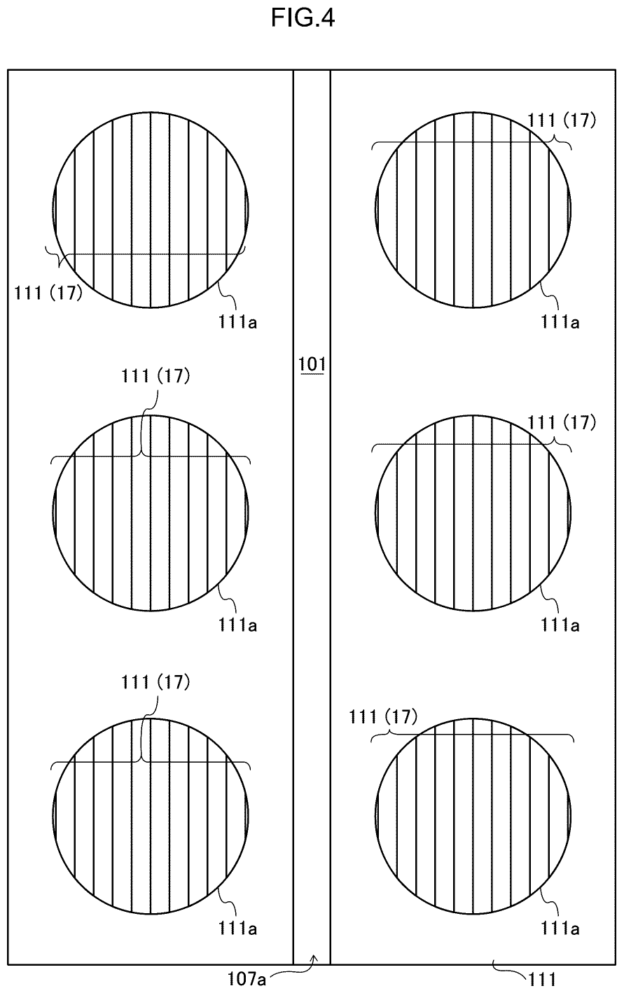

FIG. 4 is a plan view showing a patterned ELO mask that is formed by the twice patterning. Referring to FIG. 4, the patterned ELO mask 111 has multiple patterned regions 111a, which are separated from each other. Each of the patterned regions 111a is prepared for the monolithic grating 17 of the VCSEL 11, and apart from the openings 107a.

As shown in FIG. 3C, III nitride is grown or deposited on the substrate 101 with the patterned ELO mask 111 by MOCVD to form a thick III nitride region 113. At least part of the Ill nitride region 113 can be doped with an n-type dopant, such as silicon. In the present example, the III nitride region 113 can completely cover the grating 17. The Ill nitride region 113 can be provided with a larger thickness than that of the nitride region 25. The ELO region of III nitride can include a defect density of less than 105/cm², 104/cm² or 103/cm².

As shown in FIG. 3D, before subsequent semiconductor deposition, the Ill nitride region 113 can be processed so as to obtain a desired length of the optical cavity 29. For example, the III nitride region 113 may be polished or etched to form the planarized Ill nitride region 115, and the polished or etched surface of the Ill nitride region 115 is made planarized to be ready to subsequent epitaxial growth.

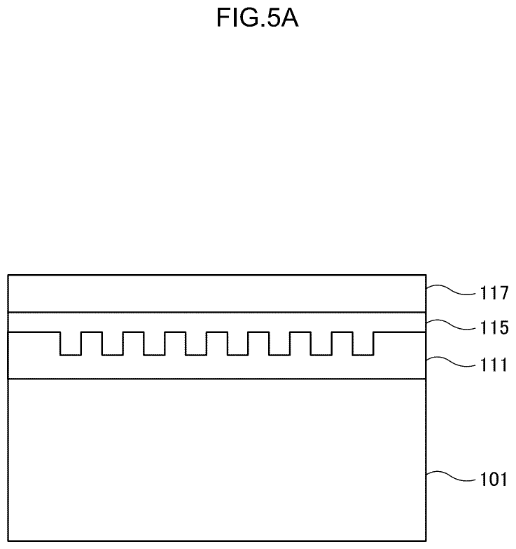

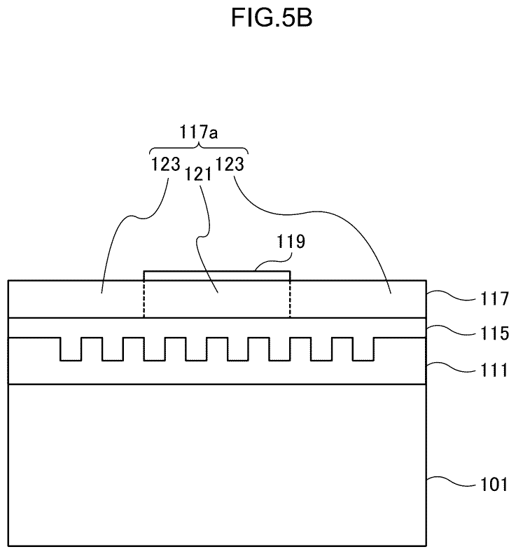

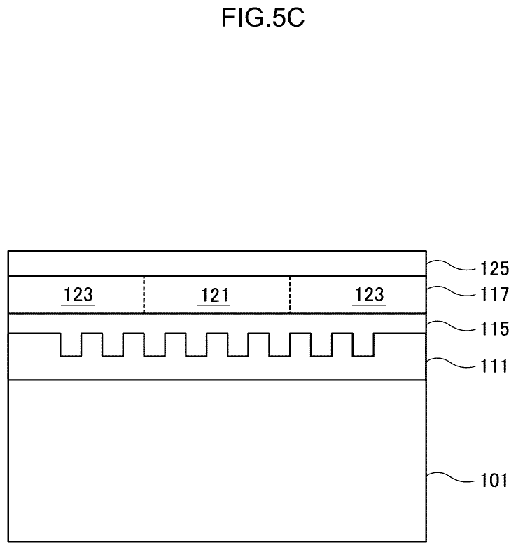

FIGS. 5A, 5B, and 5C show steps for fabricating the VCSEL 11. After the planarization of the III nitride region 113, as shown in FIG. 5A, a semiconductor laminate 117 is grown which includes the Ill nitride region 25, the Ill nitride active region 27, and the p-type III nitride region 23. The nitride region 25 can include GaN- or AlN-based material doped with n-type dopant, which allows the supply of electrons to the III nitride active region 27, and the p-type III nitride region 23 can include GaN- or AlN-based material doped with p-type dopant, which allows the supply of holes to the Ill nitride active region 27. The Ill nitride active region 27 can include GaN- or AlN-based material, such as GaN, InGaN, AlN or AlGaN. The Ill nitride active region 27 may be provided with a single layer or a quantum well structure, such as single quantum well (SQW) or multiple quantum wells (MQWs). If needed, the buried tunnel junction can be grown after depositing the p-type Ill nitride region 23.

As shown in FIG. 5B, in order to produce a semiconductor aperture region from the semiconductor laminate 117 and the polished III nitride region 115, a mask 119, such as resist, is formed on the semiconductor laminate 117. The implantation of ion, such as hydrogen atom, n-type dopant atom, and/or p-type dopant atom, into the semiconductor laminate 117 with a mask 119 produces a aperture structure 117a for the semiconductor section 15 from the semiconductor laminate 115. The aperture structure 117a is provided with a semiconductor aperture region 121 and an isolation region 123 which surrounds the semiconductor aperture region 121.

The former part of the exemplary method for fabricating the VCSEL has been described as above. Then, a description will be given of the latter part of the exemplary method according to the present embodiment below.

After removing the mask 119, as shown in FIG. 5C, a conductive layer 125 is deposited on the aperture structure 117a, which covers the semiconductor aperture region 121 and the isolation region 123. The conductive layer 125 may include a heavily-doped III nitride semiconductor layer, such as GaN or AlGaN, and/or an inorganic layer, such indium tin oxide (ITO), and is transparent to light from the Ill nitride active region 27.

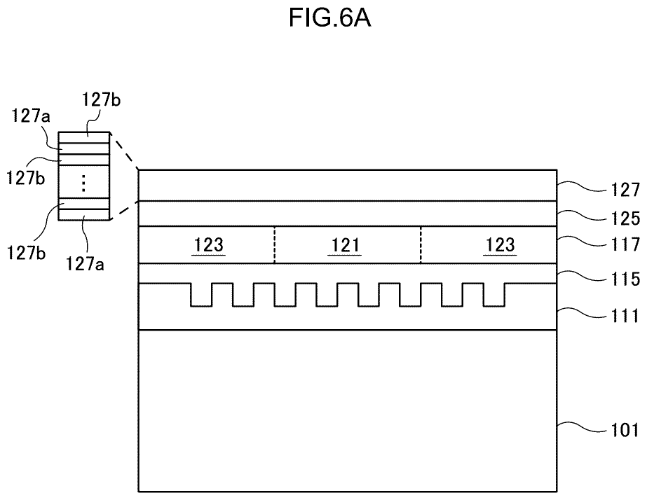

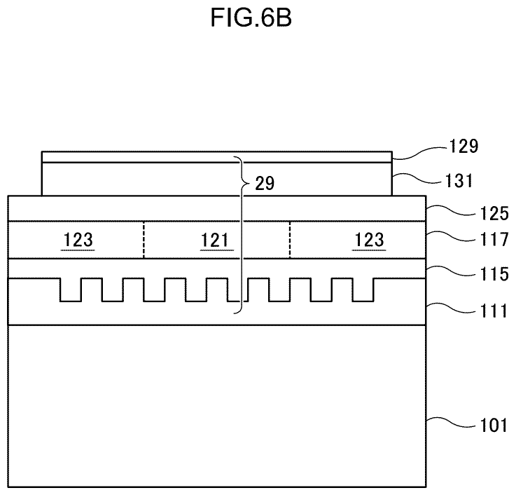

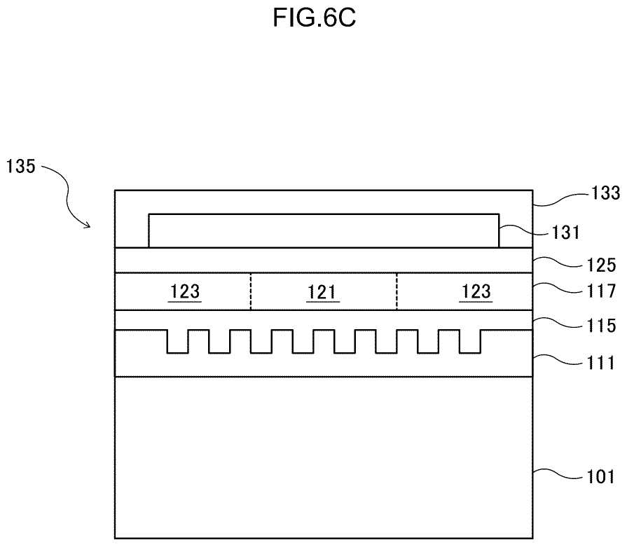

FIGS. 6A, 6B, and 6C show steps for fabricating the VCSEL 11. As shown in FIG. 6A, a distributed Bragg reflector (DBR) laminate 127 is formed on the conductive layer 125, and specifically, first dielectric layers 127a and second dielectric layers 127b are deposited alternately to form the arrangement of these dielectric layers.

As shown in FIG. 6B, a mask 129, such as resist, is formed on the DBR laminate 127. The DBR laminate 127 is etched with the mask 129 so as to expose a part of the conductive layer 125, thereby forming a patterned DBR laminate 131, i.e., a DBR 131. The DBR 131 is positioned to the monolithic grating 17 that is associated with the patterned ELO mask 111 (17), thereby providing the VCSEL 11 with the substantial portion of the optical cavity 29.

As shown in FIG. 6C, a first electrode 133, such as anode metal electrode, is formed over the DBR 127 to provide a product 135. The first electrode 133 is disposed in contact with the exposed face of the conductive layer 125.

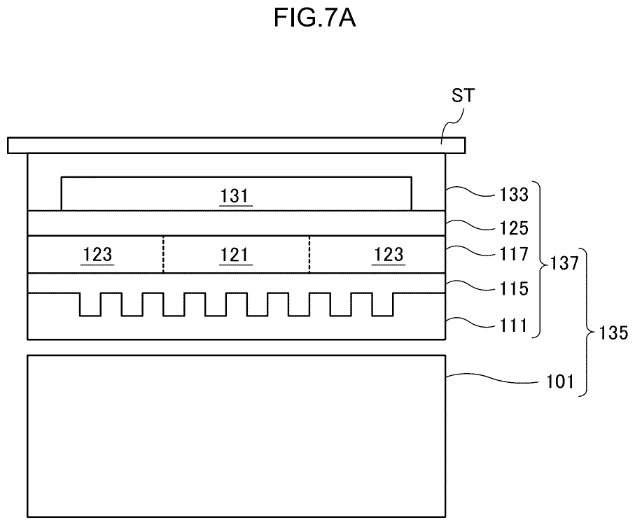

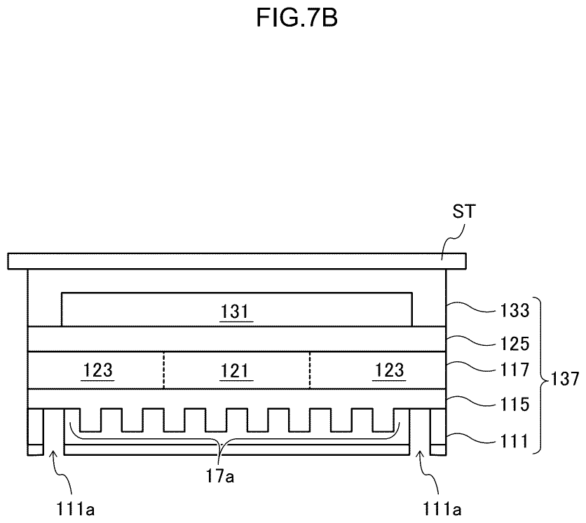

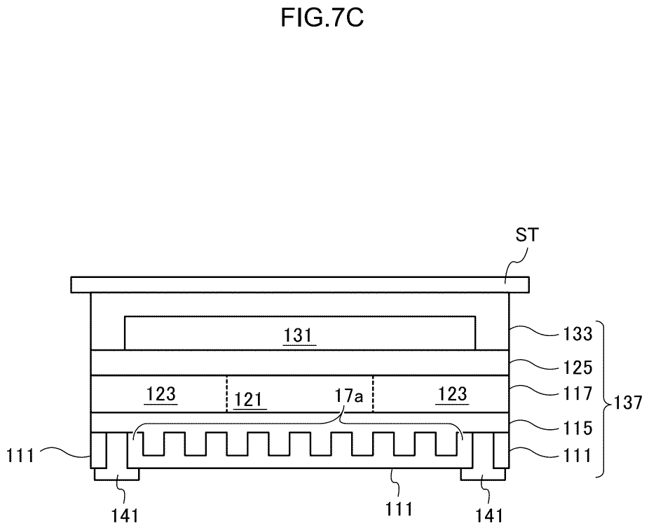

FIGS. 7A, 7B, and 7C show steps for fabricating the VCSEL 11. As shown in FIG. 7A, the product 135 is bonded to a supporting tool ST at the first electrode 133.

The substrate 101 is removed from the product 135 by either cryogenic treatment or laser lift-off to expose the patterned ELO mask 111 that is associated with the monolithic grating 17, thereby fabricating a VCSEL laminate 137. The VCSEL laminate 137 has been provided with the first electrode 133, which is located on the front side thereof.

As shown in FIG. 7B, in order to form a second electrode, such as a cathode metal electrode, on the VCSEL laminate 137, the patterned ELO mask 111 is processed with the mask 139, such as resist, to form openings 111b therein by photo lithography and etching.

As shown in FIG. 7C, after removing the mask 139, the second electrode 141 is formed on the back side of the VCSEL laminate 137 to fabricate a VCSEL, which is provided with the first electrode 133 and the second electrode 141 on the respective opposite sides of the VCSEL 11. The second electrode 141 is disposed in contact with the back side of the III-nitride region 115.

The above processes complete the fabrication of a type of the VCSEL 11.

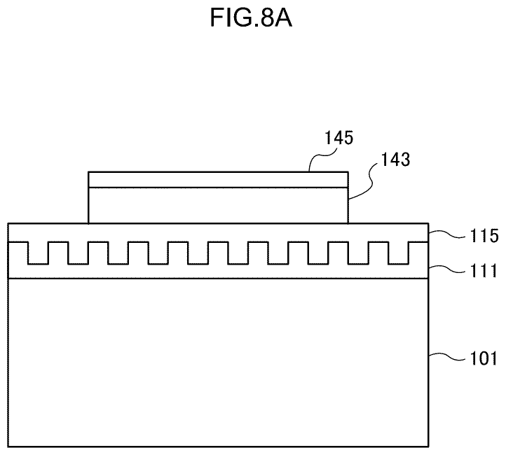

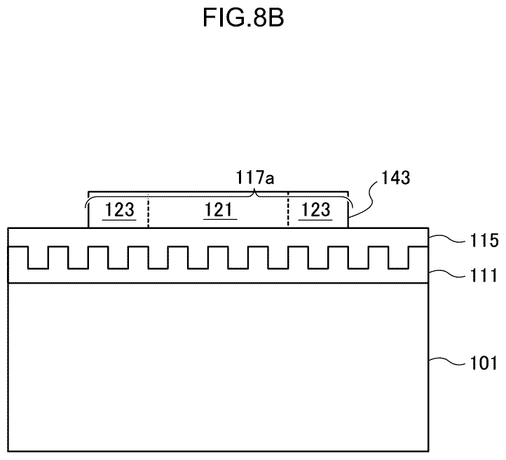

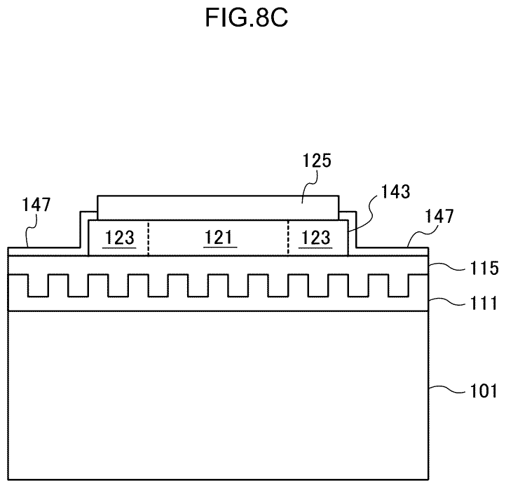

A description will be given of an exemplary VCSEL according to the present embodiment below. FIGS. 8A, 8B, and 8C show steps for fabricating the VCSEL 11.

After forming the semiconductor laminate 117 as shown in FIG. 5A, as shown in FIGS. 8A and 8B, a semiconductor mesa 143 and the aperture structure 117a are produced from the semiconductor laminate 117 to expose the n-type Ill-nitride region 115. In the present example, as shown in FIG. 8A, the semiconductor mesa 143 is first formed by photo lithography and etching with a mask 145, such as resist, and then the aperture structure 117a is formed as shown in FIG. 5B. Referring to FIG. 8B, the aperture structure 117a is provided with a semiconductor aperture region 121 and an isolation region 123 which surrounds the semiconductor aperture region 121. If needed, the aperture structure 117a may be first formed, and then the semiconductor mesa 143 may be formed.

As shown in FIG. 8C, a conductive layer 125 is grown on the aperture structure 117a, and the conductive layer 125 covers the semiconductor aperture region 121 and the isolation region 123 and is not grown on the n-type III nitride region 115. The conductive layer 125 is transparent to light from the Ill nitride active region 27. The conductive layer 125 may also include a heavily-doped III nitride semiconductor layer, such as GaN or AlGaN, and/or an inorganic layer, such indium tin oxide (ITO). The conductive layer 125 of III nitride semiconductor can be formed on the semiconductor mesa 143, for example, by selective growth with an inorganic mask or dielectric mask 147.

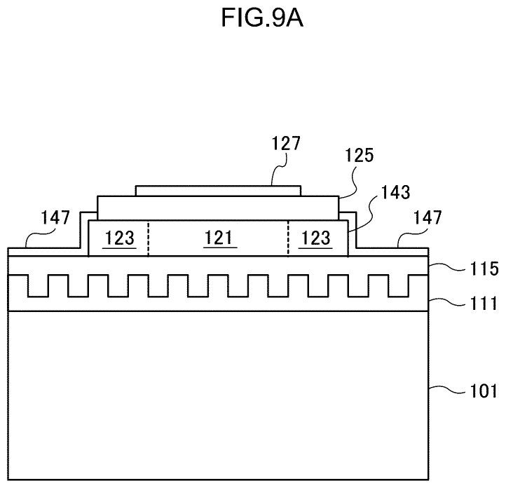

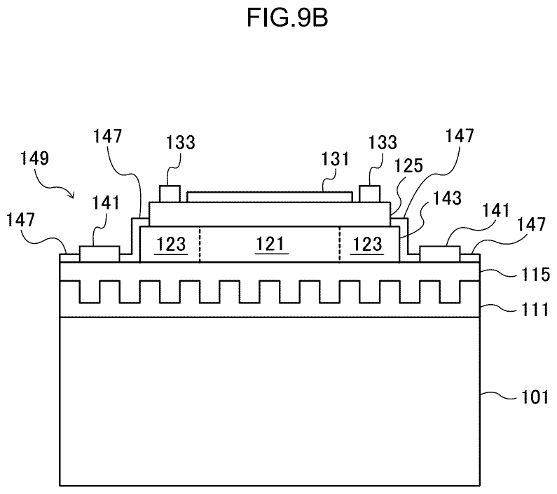

FIGS. 9A and 9B show steps for fabricating the VCSEL 11. As shown in FIG. 9A, a DBR laminate 127 is formed on the conductive layer 125. A part of the DBR laminate 127 is removed by etching so as to expose a part of the conductive layer 125, thereby forming a patterned DBR laminate 131, i.e., a DBR 131. The DBR 131 is positioned to the monolithic grating 17 that is associated with the patterned ELO mask 111 (17), thereby providing the VCSEL 11 with the substantial portion of the optical cavity 29.

As shown in FIG. 9B, a first electrode 133, such as an anode metal electrode, and a second electrode 141, such as a cathode metal electrode, are formed on the exposed conductive layer 125 and the exposed n-type Ill nitride region 115, respectively, thereby fabricating a product 149. The first electrode 133 and the second electrode 141 both are located on the front side of the semiconductor regions (125 and 115). Specifically, the first electrode 133 is in disposed contact with the conductive layer 125 on the mesa 143, and the second electrode 141 is disposed in contact with the n-type III nitride region 115.

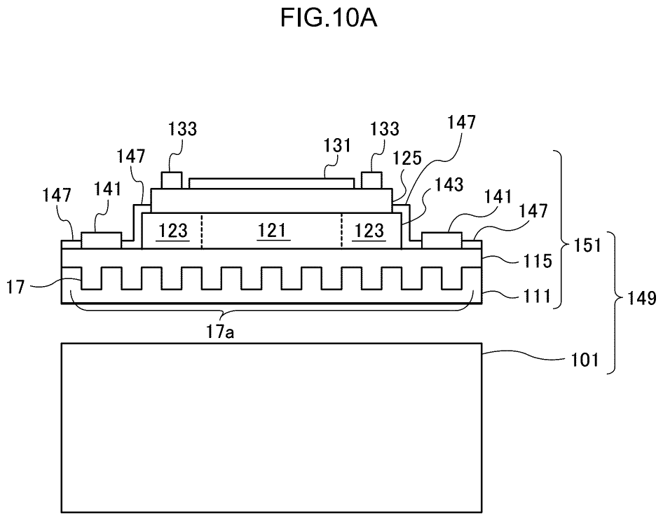

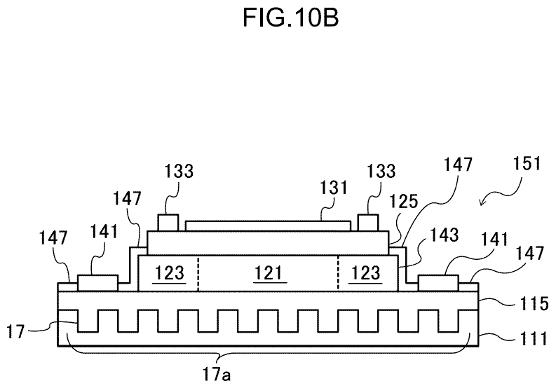

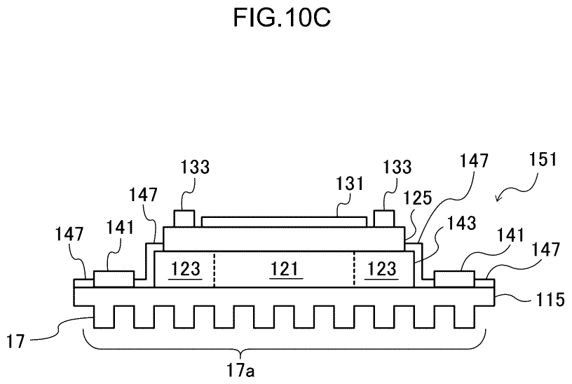

FIGS. 10A, 10B, and 10C show steps for fabricating the VCSEL 11. The product 149 is bonded to a supporting tool in the same manner as shown in FIG. 6C, and the supporting tool is omitted in FIGS. 9B to 10C for simplicity.

As shown in FIG. 10A, the substrate 101 is removed from the product 149 to expose the patterned ELO mask 111 that is associated with the monolithic grating 17, thereby fabricating a VCSEL laminate 151. The VCSEL laminate 151 has been provided with the first electrode 133 and the second electrode 141, which are located on the same side thereof.

As shown in FIG. 10B, in the VCSEL that has the first and second electrodes on the same side thereof, the patterned ELO mask 111 is left on the backside of the Ill nitride region 115. The above processes complete the fabrication of a type of the VCSEL 11.

If needed, as shown in FIG. 10C, the dielectric material of the patterned ELO mask 111 may be removed to expose the periodic one-dimensional pattern 17a, which is transferred from the patterned ELO mask 111 to the Ill nitride region 115. Accordingly, the monolithic grating 17 is formed on the backside of the Ill nitride region 115.

The above processes complete the fabrication of a type of the VCSEL 11.

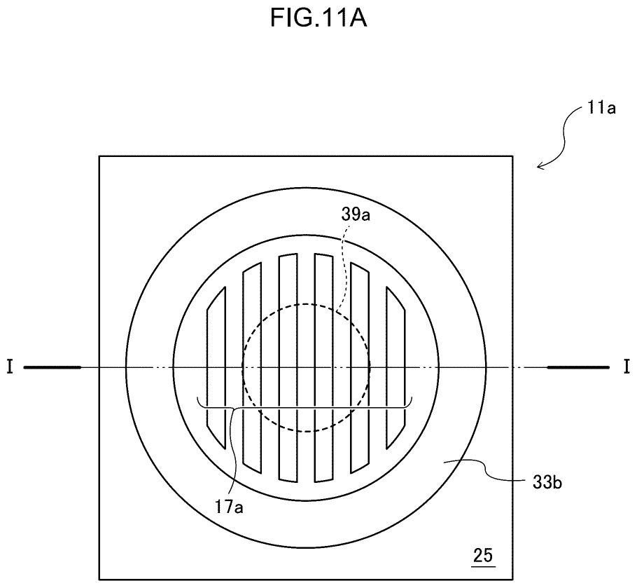

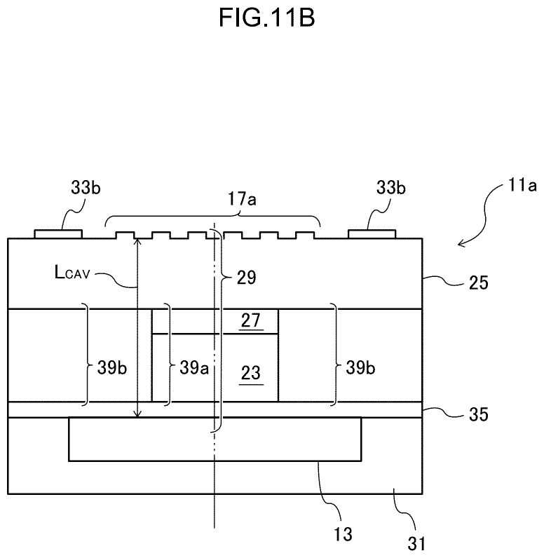

A description will be given of multiple exemplary VCSELs according to the present embodiment below with reference to FIGS. 11 to 15. The DBR mirror 13 can also function as passivation/isolation layer between p- and n-electrodes.

FIG. 11A is a plan view showing a VCSEL 11a according to the present embodiment, and FIG. 11B is a cross sectional view, taken along I-I line shown in FIG. 11A.

An example process includes the following steps.

1. Depositing an ELO dielectric mask layer on a host substrate, such as a GaN substrate, GaN-on-Sapphire template, or GaN-on-Si template

2. Patterning a grating in the ELO mask

3. Forming a growth assist portion, i.e., openings, in the ELO mask layer to expose the surface of the host substrate 101, thereby forming a patterned ELO mask 111

4. Growing a GaN layer on the mask by epitaxial lateral overgrowth procedure so as to allow the layer thus laterally grown to at least cover the grating pattern of the patterned ELO mask, thereby forming an epitaxial lateral overgrown (ELO) nitride layer

5. Planarizing the overgrown nitride layer by polishing or etching to control the length of the optical cavity

6. Forming a semiconductor laminate by resuming the growth for the following layers: an n-GaN layer (for example, about 1000 nm thick) for cladding and n-contact layers; an active region (for example, InGaN/GaN quantum wells); an AlGaN electron blocking layer (for example, about 30 nm); a p-GaN layer (for example, about 200 nm thick); and a p⁺-GaN layer (for example, about 10 nm thick)

7. Carrying out ion implantation to define an electrical, optical aperture in the semiconductor laminate

8. Forming a transparent conductive layer for p-contact

9. Depositing the dielectric DBR mirror laminate

10. Depositing the contact metal electrode and flip chip bonding to a supporting tool (not shown in the Figure).

11. Removing the substrate either using cryogenic treatment mentioned in Refs. (NPL16) to (NPL20) or by laser liftoff when template substrates are used, where removing the substrate allows for repeated use of the same substrate, thereby significantly reducing the cost.

12. Finally depositing an metal contact electrode on the n-side

13. Removing the patterned ELO mask 111

The monolithic grating 17 is provided on the surface of the Ill nitride region 25, such as n-GaN or unintendedly doped (UID)-GaN, which is grown over the patterned ELO mask 111 by epitaxial lateral overgrowth technique. The Ill nitride thus grown contains the GaN grating, which is transferred from the patterned ELO mask 111. The Ill nitride regions 23 and 27 may be grown by MOCVD after forming the Ill nitride region 25 by polishing, which can be used to adjust the cavity length and/or planarize the Ill nitride region. The III nitride regions 23 and 27, which are resumed device layers, include an undoped active region and p-type layers, each of which contains the alloy of In, Ga, and/or Al, and N.

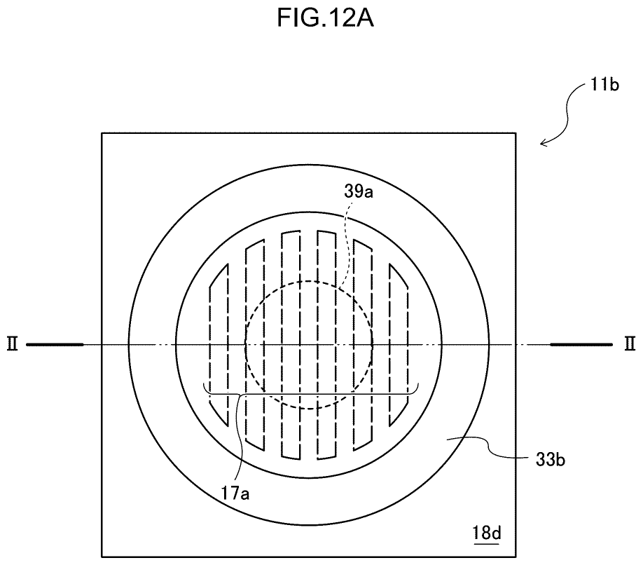

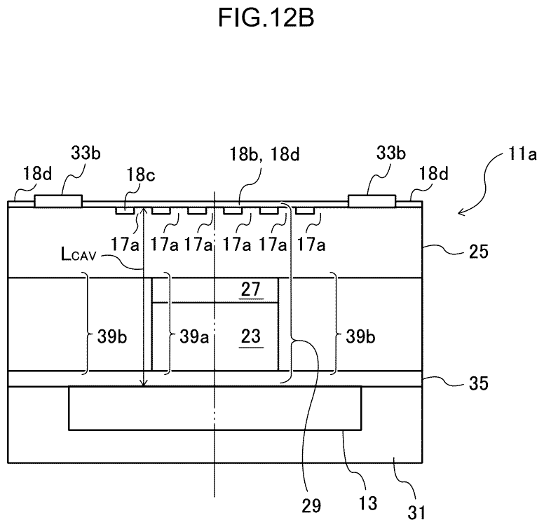

FIG. 12A is a plan view showing a VCSEL 11b according to the present embodiment, and FIG. 12B is a cross sectional view, taken along II-II line shown in FIG. 12B.

An example process includes the following steps.

1. Forming a DBR mirror laminate (18d) of dielectric layers, which are periodically arranged, on a host substrate (101), such as a GaN substrate, GaN-on-Sapphire template, or GaN-on-Si template

2. Depositing a separate dielectric layer (18c) on the DBR mirror laminate (18d)

3. Forming a grating pattern for a monolithic grating pattern in the separate dielectric layer (18c)

4. Forming a growth assist portion, i.e., an opening in the separate dielectric layer (17c) and the DBR mirror laminate (18d) to expose the surface of the host substrate 101, thereby forming the patterned ELO mask 111

5. Growing a GaN layer on the mask by epitaxial lateral overgrowth procedure so as to allow the layer thus laterally grown to at least cover the grating pattern, thereby forming an ELO nitride layer

6. Planarizing the ELO nitride layer (113) by polishing or etching to control cavity length

7. Forming a semiconductor laminate by resuming the growth for the following layers: an n-GaN layer (for example, about 1000 nm thick) for cladding and n-contact layers; an active region (for example, InGaN/GaN quantum wells); an AlGaN electron blocking layer (for example, about 30 nm); a p-GaN layer (for example, about 200 nm thick); and a p⁺-GaN layer (for example, about 10 nm thick)

8. Carrying out ion implantation to define an electrical, optical aperture

9. Depositing a transparent conductive layer (35) for p-contact

10. Depositing a dielectric DBR mirror laminate (13)

11. Depositing a contact metal electrode (31) and flip chip bonding to a supporting tool (not shown in the FIG.

12. Removing the substrate (101) by either cryogenic treatment in Refs. (NPL16) to (NPL20) or by laser lift-off when template substrates are used, where removing the substrate allows for repeated use of the same substrate, thereby reducing significantly the cost

13. Finally depositing a metal contact electrode (33b) on the n-side

The monolithic grating 17 are provided on the surface of the III nitride region 25, such as n-GaN or UID-GaN, which is grown over the patterned ELO mask 111 by epitaxial lateral overgrowth technique. The Ill nitride thus grown contains the GaN grating, which is transferred from the patterned ELO mask 111, and the patterned ELO mask 111 is provided with the additional DBR mirror (18d). The additional DBR mirror (18d) is disposed adjacent to the GaN grating (17a) thereon to be coupled with the grating (17a), thereby configuring a single mirror. The III nitride regions 23 and 27 may be grown by MOCVD after forming the III nitride region 25 by polishing which can adjust the cavity length and/or planarize the III nitride region. The Ill nitride regions 23 and 27, which are resumed device layers, include an undoped active region and p-type layers, respectively, each of which contains the alloy of In, Ga, and/or Al, and N.

The periodic one-dimensional pattern 17a and the additional DBR mirror (18d), which is disposed in contact with the periodic one-dimensional pattern 17a and the dielectric layer containing the periodic one-dimensional pattern 18a, are coupled to enhance the reflectivity without complexity.

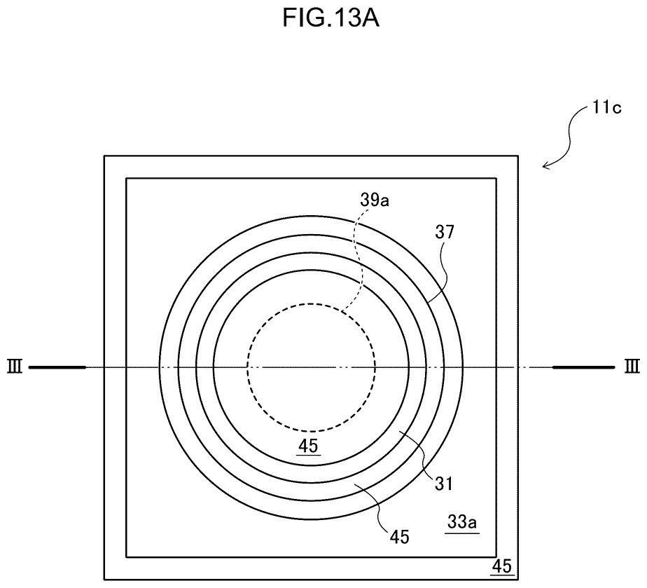

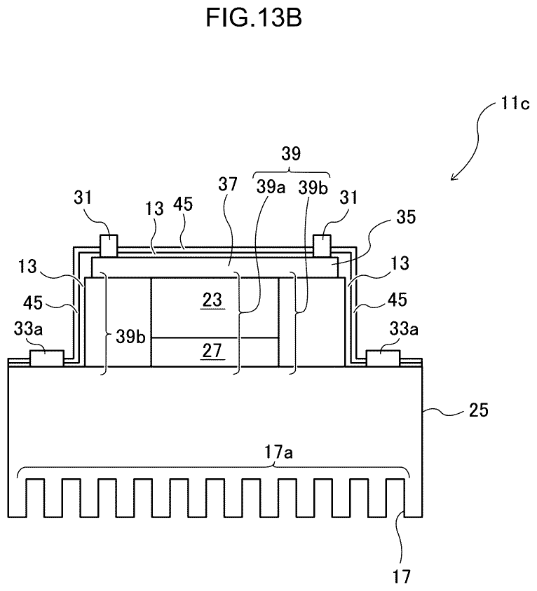

FIG. 13A is a plan view showing a VCSEL 11c according to the present embodiment, and FIG. 13B is a cross sectional view, taken along III-III line shown in FIG. 13A.

An example process includes the following steps.

1. Forming an ELO dielectric mask layer on a host substrate, such as a GaN substrate, GaN-on-Sapphire template, or GaN-on-Si template

2. Patterning a grating on the ELO mask layer

3. Forming a growth assist portion, i.e., an opening, in the ELO mask layer to expose the surface of the host substrate 101, thereby forming a patterned ELO mask 111

4. Growing a GaN layer on the ELO mask by epitaxial lateral overgrowth procedure so as to allow the layer thus laterally grown to at least cover the grating pattern, thereby forming an ELO nitride layer

5. Planarizing the ELO nitride layer by polishing or etching to control the length of the optical cavity

6. Forming a semiconductor laminate by resuming the growth for the following layers: an n-GaN layer (for example, about 1000 nm thick) for cladding and n-contact layers; an active region (for example, InGaN/GaN quantum wells); an AlGaN electron blocking layer (for example, about 30 nm); a p-GaN layer (for example, about 200 nm thick); and a p⁺-GaN layer (for example, about 10 nm thick)

7. Producing a mesa from the semiconductor laminate to form an n-GaN contact region in the semiconductor laminate

8. Carrying out ion implantation to define an electrical, optical aperture

9. Depositing a transparent conductive layer (35) for p-contact

10. Depositing the dielectric DBR mirror (13) (which can be used as isolation between p-side and n-side pads)

11. Depositing contact metal electrodes (31 and 33a) and flip chip bonding to a supporting tool (not shown in the figure).

12. Removing the substrate 101 by either cryogenic treatment in Refs. (NPL16) to (NPL20) or by laser lift-off when template substrates are used. Removing the substrate allows for repeated use of the same substrate, thereby significantly reducing the cost.

13. Removing the patterned ELO mask 111 to expose the Ill nitride region 25, the backside of which is provided with the periodic one-dimensional pattern 17a of the monolithic grating 17.

The dielectric DBR mirror 13 is located on the conductive layer 35, which is disposed on the top of the mesa 37, and extends from the anode electrode 31 to the cathode electrode 33a to cover the top and side faces of the mesa 37. Another dielectric material film 45 may be located on the dielectric DBR mirror 13, and extend from the anode electrode 31 to the cathode electrode 33a thereon. The dielectric DBR mirror 13 and, if any, the other dielectric material film 45 serve as a passivation film. The mesa 37 allows the anode electrode 31 and the cathode electrode 33a to be located on the same side of the VCSEL 11c, which can be mounted in a flip-chip bonding manner.

The monolithic grating 17 are provided on the surface of the Ill nitride region 25, such as n-GaN or UID-GaN, which is grown over the patterned ELO mask 111 by epitaxial lateral overgrowth technique. The III nitride thus grown contains the GaN grating, which is transferred from the patterned ELO mask 111. The Ill nitride regions 23 and 27 may be grown by MOCVD after forming the Ill nitride region 25 by polishing or etching, which can be used to adjust the cavity length and/or planarize the Ill nitride region. The Ill nitride regions 23 and 27, which are resumed device layers, include an undoped active layer and p-type layers, respectively, each of which contains the alloy of In, Ga, and/or Al, and N.

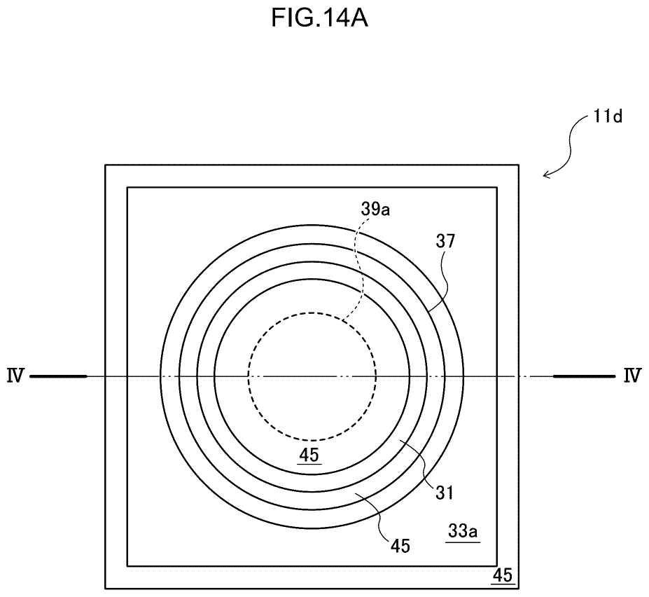

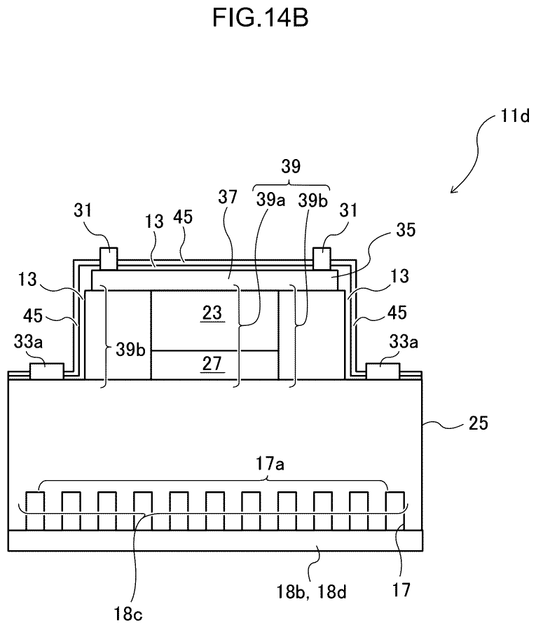

FIG. 14A is a plan view showing a VCSEL 11d according to the present embodiment, and FIG. 14B is a cross sectional view, taken along IV-IV line shown in FIG. 14A.

An example process includes the following steps.

1. Forming a DBR mirror laminate (18d) of dielectric layers, which are periodically arranged, on a host substrate 101, such as a GaN substrate, GaN-on-Sapphire template, or GaN-on-Si template

2. Depositing a separate dielectric layer (18c) on the DBR mirror laminate (18d)

3. Forming a monolithic grating pattern in the separate dielectric layer (18c)

4. Forming a growth assist portion, i.e., an opening in the separate dielectric layer (18c) and the DBR mirror laminate (18d) to expose the surface of the host substrate 101, thereby forming the patterned ELO mask 111

5. Growing a GaN layer on the mask by epitaxial lateral overgrowth procedure so as to allow the layer thus laterally grown to at least cover the grating pattern, thereby forming an ELO nitride layer

6. Planarizing the ELO nitride layer (113) by polishing or etching to control cavity length

7. Forming a semiconductor laminate by resuming the growth for the following layers: an n-GaN layer (for example, about 1000 nm thick) for cladding and n-contact layers; an active region (for example, InGaN/GaN quantum wells); AlGaN electron blocking layer (for example, about 30 nm); a p-GaN layer (for example, about 200 nm thick); and a p⁺-GaN layer (for example, about 10 nm thick)

8. Producing a mesa from the semiconductor laminate to form a contact n-GaN region in the semiconductor laminate

9. Carrying out ion implantation to define an electrical, optical aperture

10. Depositing a transparent conductive layer (35) for p-contact

11. Depositing the dielectric DBR mirror (13) (which can be used as isolation between p-side pads and n-side pads)

12. Depositing contact metal electrodes (31 and 33a) and flip chip bonding to a supporting tool (not shown in the figure).

13. Removing the substrate 101 by either cryogenic treatment in Refs. (NPL16) to (NPL20) or by laser lift-off when template substrates are used. Removing the substrate allows for repeated use of the same substrate, thereby significantly reducing the cost.

The dielectric DBR mirror 13 is located on the conductive layer 35, which is disposed on the top of the mesa 37, and extends from the anode electrode 31 to the cathode electrode 33a to cover the top and side faces of the mesa 37. Another dielectric material film 45 may be located on the dielectric DBR mirror 13, and extend from the anode electrode 31 to the cathode electrode 33a thereon. The dielectric DBR mirror 13 and, if any, the other dielectric material film 45 serve as a passivation film. The mesa 37 allows the anode electrode 31 and the cathode electrode 33a to be located on the same side of the VCSEL 11d, which can be mounted in a flip-chip bonding manner.

The monolithic grating 17 are provided on the surface of the Ill nitride region 25, such as n-GaN or UID-GaN, which is grown over the patterned ELO mask 111 by epitaxial lateral overgrowth technique. The III nitride thus grown contains the GaN grating, which is transferred from the patterned ELO mask 111, and the patterned ELO mask 111 is provided with the additional DBR mirror (18d). The additional DBR mirror (18d) is disposed adjacent to the GaN grating (17a) thereon to be coupled with the grating (17a), thereby configuring a single mirror. The periodic one-dimensional pattern 17a and the additional DBR mirror (18d), which is disposed in contact with the periodic one-dimensional pattern 17a and the dielectric layer containing the periodic one-dimensional pattern 18a, are coupled to enhance the reflectivity without complexity. The Ill nitride regions 23 and 27 may be grown by MOCVD after forming the Ill nitride region 25 by polishing or etching, which can adjust the cavity length and/or planarize the Ill nitride region. The III nitride regions 23 and 27, which are resumed device layers, include an undoped active region and p-type layers, respectively, each of which contains the alloy of In, Ga, and/or Al, and N.

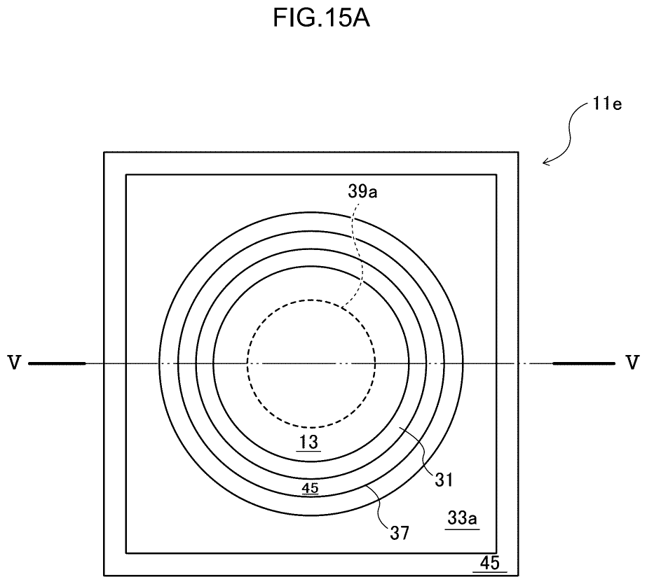

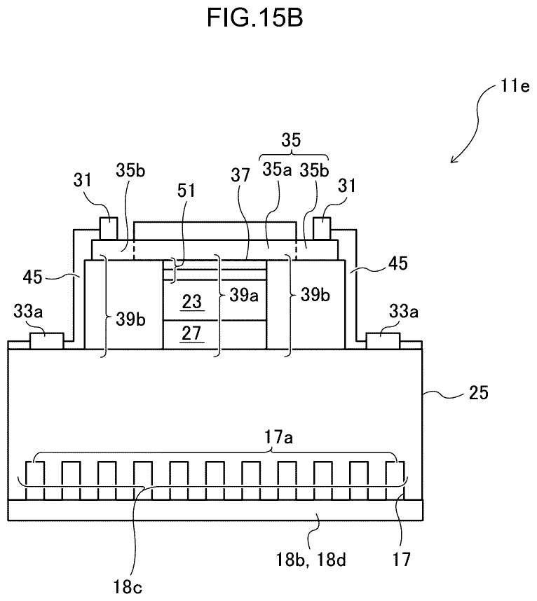

FIG. 15A is a plan view showing a VCSEL 11e according to the present embodiment, and FIG. 15B is a cross sectional view, taken along V-V line shown in FIG. 15A.

An example process includes the following steps.

1. Forming an ELO mask on a host substrate, such as a GaN substrate, GaN-on-Sapphire template, or GaN-on-Si template

2. Patterning a grating on the ELO mask

3. Forming a growth assist portion to the host substrate

4. Growing a GaN layer on the mask by epitaxial lateral overgrowth procedure so as to allow the layer thus laterally grown to at least cover the grating pattern, thereby forming an ELO nitride layer

5. Planarizing the ELO nitride layer by polishing or etching to control the length of the optical cavity

6. Forming a semiconductor laminate by resuming the growth for the following layers: an n-GaN layer (for example, about 1000 nm thick) for cladding and n-contact layers; an active region (for example, InGaN/GaN or InGaN/InGaN quantum wells); an AlGaN electron blocking layer (for example, about 30 nm); a p-GaN layer (for example, about 200 nm thick); and a buried tunnel junction (51) including a p⁺⁺-GaN layer (for example, about 10 nm thick) and n⁺⁺-GaN layer (for example, about 10 nm)

7. Producing a mesa from the semiconductor laminate to form a contact n-GaN region

8. Carrying out ion implantation to define an electrical, optical aperture

9. Depositing a transparent conductive layer (35) for p-contact

10. Depositing the dielectric DBR mirror (13) and the passivation film 45

11. Depositing contact metal electrodes (31) and flip chip bonding to a supporting tool (not shown in the figure).

12. Removing the substrate (101) by either cryogenic treatment in Refs. (NPL16) to (NPL20) or by laser lift-off when template substrates are used. Removing the substrate allows for repeated use of the same substrate, thereby significantly reducing the cost.

The VCSEL 11e further includes a buried tunnel junction 51 disposed between the p-type Ill nitride region 23 and the DBR 13. The buried tunnel junction 51 includes a heavily-doped p-type III nitride, such as p⁺⁺-GaN, and a heavily-doped n-type III nitride, such as n⁺⁺-GaN. In an example, the p⁺⁺-GaN layer is deposited on the p-type III nitride region 23, and then the n⁺⁺-GaN layer is deposited on the p⁺⁺-GaN layer to form a tunnel junction. The n⁺⁺-GaN layer is disposed in contact with the n-type conductive layer 35. At the tunnel junction, the conductive type of the Ill nitride is changed to the other conductive type. An inverse bias voltage is applied to the tunnel junction so that carriers pass through the junction by tunneling.

The tunnel junction 51 in the present example can be applied to any one of the former exemplary VCSELs 11a to 11d. The inclusion of the tunnel junction improves performance of VCSELs and mitigates ITO absorption.

The dielectric DBR mirror 13 is located on the conductive layer 35, which is disposed on the top of the mesa 37. The dielectric material film 45 or the dielectric DBR mirror 13 extends from the anode electrode 31 to the cathode electrode 33a to cover the top and side faces of the mesa 37, and serves as a passivation film. The mesa 37 allows the anode electrode 31 and the cathode electrode 33a to be located on the same side of the VCSEL 11e, which can be mounted in a flip-chip bonding manner.

The monolithic grating 17 is provided on the surface of the Ill nitride region 25, such as n-GaN or UID-GaN, which is grown over the patterned ELO mask 111 by epitaxial lateral overgrowth technique. The III nitride thus grown contains the GaN grating, which is transferred from the patterned ELO mask 111. The III nitride regions 23 and 27 and the buried tunnel junction 51 may be grown by MOCVD after forming the Ill nitride region 25 by polishing or etching, which can be used to adjust the cavity length and/or planarize the III nitride region. The Ill nitride regions 23 and 27, which are resumed device layers, include an undoped active layer and p-type layers, respectively, each of which contains the alloy of In, Ga, and/or Al, and N.

A description will be given of the technical explanation of some technical terms associated with VCSELs according to the present embodiment.

### Host Substrate and ELO Mask

In one embodiment, the GaN-based layers 113 are grown by ELO on the host substrate 101 with the patterned ELO mask 111 comprised of SiO₂, and the GaN-based layers 113 do not coalesce on SiO₂. The patterned ELO mask 111 can be comprised of striped openings 107a, and the SiO₂ stripes of the patterned ELO mask 111 define the distance between the openings 107a, allowing the growth of high quality III nitride semiconductor layers and avoiding the bowing or curvature of the substrate 101 during epitaxial growth due to avoidance of coalescence between neighboring semiconductor layers. This can provide VCSELs with reduced defect densities, such as dislocation and stacking faults. Moreover, these techniques can be used with a hetero-substrate, such as sapphire, SiC, LiAlO₂, Si, etc., as long as it enables growth of the ELO GaN-based layers.

### Patterning Gratings on Top of ELO Mask

A grating can be formed with the patterned ELO mask. For example, nano-imprinting is a commercially acceptable technique compared to other techniques, such as E-beam lithography or holography.

Gratings can be formed by first depositing a photosensitive material on the ELO mask and then applying a desired grating pattern to the photosensitive material. Alternatively, nano-imprinting, E-beam or Holography may also be employed to print the desired grating pattern. Then, the desired grating pattern is transferred to the photoresist material. For example, grating pattern parameters, such as height (H), period (P), and width (W), can be defined as shown in FIG. 3D, with factors H/P and W/P. Transverse electric (TE) mode map of n-GaN gratings reflectance map can be above 99% at an incident light wavelength of 405 nm when H/P is about 0.27 and W/P is about 0.35, with the period P of about 375 nm. After transferring the grating pattern onto the photoresist, a dielectric material, for example SiO₂, is deposited to embed the photoresist completely, and etching, such as reactive ion etching, is performed to expose the underlying photoresist. Then, a chemical lift-off of the photoresist leaves the grating pattern on the ELO mask, thereby forming the patterned ELO mask.

Forming the grating on the top of ELO mask containing a DBR mirror structure

Gratings can be formed by first depositing a photosensitive material on the ELO mask (in this case, the DBR mirror used as ELO mask) and then applying a desired grating pattern to the photosensitive material. Alternatively, nano-imprinting, e-beam or holography may also be used to print the desired grating pattern. Then, the desired grating pattern is transferred to the photoresist material. For example, grating pattern parameters, such as height (H), period (P), and width (W) can be defined with factors of H/P and W/P.

Once the grating pattern is transferred onto the photoresist, a dielectric material, for example SiO₂, is deposited over the pattern to embed it completely, and etching, such as reactive ion etching, is performed to expose the underlying photoresist. Then, chemical lift-off of the photoresist leaves a grating pattern in the SiO₂ layer which is located on the top of the DBR structure.

### Growth of III Nitride Layers

Next, the Ill nitride region 113 is grown by MOCVD. The Ill nitride region is provided with the shape of the grating at the bottom of the Ill nitride thus grown, as shown in FIG. 3C. The Ill nitride region 113 is polished or etched to a desired thickness to form the planarized Ill nitride region 115. After adjusting the thickness of Ill nitride layers 113 by polishing or etching, the Ill nitride laminate 117 is grown thereon.

Trimethylgallium (TMGa), trimethylindium (TMIn) and triethylaluminium (TMAl) are used as III-element sources, and ammonia (NH₃) is used as raw gas to supply nitrogen. Hydrogen (H₂) and/or nitrogen (N₂) are used as a carrier gas. Saline (SiH₄) and Bis(cyclopentadienyl)magnesium (Cp₂Mg) are used as n-type and p-type dopants, respectively.

The pressure typically can be set to 50 to 760 Torr. III nitride-based semiconductor layers are generally grown at a temperature range from 700 to 1250 degrees C.

Exemplary growth parameters include the following: TMG can be 12 sccm; NH₃ can be 8 slm; the carrier gas can be 3 slm; SiH₄ can be 1.0 sccm; and the V/III ratio can be about 7700.

In one embodiment, the growth pressure can range from 50 to 760 Torr, and the growth pressure preferably can range from 100 to 300 Torr to obtain a large width of an island-like III nitride-based semiconductor region; the growth temperature can range from 900 to 1200 degrees C.; the V/III ratio can range from 50 to 30,000 and more preferably 3000 to 10000; TMG can range from 2 to 20 sccm; NH₃ can range from 3 to 10 slm; and the carrier gas can be only hydrogen gas, or both hydrogen and nitrogen gases. After growing for about 2 to 8 hours, the ELO GaN-based layer had a thickness of about 8 to 50 micrometers and a width of about 20 to 150 micrometers, and the ELO GaN-based layer thus grown extends laterally both way along the ELO mask to provide epitaxial lateral overgrown less-defect crystalline regions (Wings).

### Ion Implantation

Ion implantation is used to form an electrical, optical aperture in the GaN-based layer by damaging the GaN-based layer outside the aperture, and damaged GaN-based material is no longer conductive. This method keeps the surface planar and can provide a very slight index guiding between the aperture region and the damaged region. The damaged region can be, however, provided with the potential to increase an optical loss in the cavity, and tends to have higher absorption values than the un-implanted material of the aperture region. Heavy ions, such as aluminum (Al), boron (B), etc., can be used for ion implantation procedure.

### Transparent Conductive Layer

ITO can be used as a commonly used transparent current spreading layer. The inclusion of ITO to the VCSEL may cause an additional absorption, but the additional absorption can be decreased by making the intensity of the electro-magnetic wave low around the ITO layer. Alternative approaches, such as tunnel junctions, can also be used to spread current and make the optical absorption low.

### Tunnel Junction

Tunnel junctions provide an alternative to the ITO use. A tunnel junction allows hole injection into the p-side of the device through an n-type semiconductor. This is achieved by using a junction between a highly-doped n-type region and a highly-doped p-type region under a reverse bias, allowing electrons to tunnel from the valence band of the p-type region to the conduction band of the n-type region.

### Dielectric Bragg Reflector (DBR)

Traditionally, VCSELs utilize an epitaxial DBR, consisting of either AlN/GaN or AlInN/GaN bilayers or dielectric DBR mirror. The main considerations in choosing a DBR design involves the ease of fabrication, the DBR mirror includes alternating dielectric layers joined together to form a reflective mirror on top of the resonant cavity of the VCSEL. For example, a combination of SiO₂/Ta₂O₅ dielectric layers can be used as a dielectric DBR mirror.

### Monolithic Epitaxial GaN Grating

An important part of VCSELs is reflectors. Typically, dielectric DBRs are used as mirrors. However, in terms of electrical injection or thermal management concerns, at least one side of mirrors for the resonant cavity of VCSEL should be replaced with a better alternative. In the present VCSELs, monolithic gratings are used, which are formed on the epitaxial lateral overgrown wing of GaN, as a good alternative for one of the DBR mirrors.

The Monolithic epitaxial GaN grating has a periodic structure, such as GaN recess or GaN protrusions arranged on the surface of the GaN, where height (H), width (W) and period (P) of the arrangement are comparable to the wavelength of the VCSEL. When light impinges vertically onto the gratings, it diffracts into various directions depending on wavelength and period of gratings. By choosing the grating period and filling factors such as W/P and H/P appropriately, all the light energy can be made reflected back.

There are several alternatives to demonstrate gratings, but this disclosure provides a unique way to demonstrate subwavelength gratings on the device, and this way prevents the device layers from exposing to any etching environment during the fabrication process.

### Metal Pads

Metals, such as gold (Au), aluminum (Al), nickel (Ni), palladium (Pd), titanium (Ti), and so on, are used as material of metal pads. The metal layer can be formed by sputtering, evaporating, or plating.

The present disclosure relates to an improved fabrication method which demonstrates a monolithic grating for III nitride VCSELs. Specifically, the present disclosure comprises a VCSEL having a monolithic GaN grating as one of the reflective mirrors of the VCSEL operating at visible or ultraviolet wavelengths. The novel and inventive feature of the disclosure is integration of the grating through epitaxial lateral overgrowth. This approach can avoid the exposure of the device layers to physical etching during the fabrication process. In physical etching, semiconducting device layers are bombarded with heavy ions, such as aluminum or boron, to form a desired grating shape. Such a process eventually increases the resistance of layers due to the bombardment of ions, and may introduce current leakage paths. Additionally, such a practice could damage the device active region or the adjacent epitaxial layers. The process detailed in this disclosure is expected to provide a significant improvement in the device performance and reduction in the fabrication cost by eliminating complex procedures. This disclosure simplifies the fabrication of gratings operating at wavelengths in the VCSEL. This disclosure is of interest applications in Refs. (NPL7) to (NPL15) for lasers emitting visible light for data communication, LiDAR, biochemical and environmental sensing, scientific instrumentation, holographic data storage, and augmented/virtual (AR/VR) displays and illumination. Since cleaved facets or etched facets are not necessary for laser operation, the disclosure will be useful in the hybrid integration with other optoelectronic components, such as Silicon photonics.

The use of the monolithic epitaxial gratings has the following advantages.

Use of a sufficiently long cavity without excessive diffraction loss, with two reflective mirrors defining the VCSEL cavity, where this disclosure proposes to use n-GaN for grating placement, and designing a grating pattern in the vicinity of the active region, i.e., on the p-side would be complex and may damage the device layers

Better Thermal Management Due to a Long-Enough Cavity and/or Contacts Placement on Nitride Layers

Gratings generally placed on p-GaN side of the device to facilitate an easy fabrication at the expense of damage, where but the formation of gratings on the n-side requires substrate removal, which is complex, tedious and not available for all the Ill nitride crystal planes

N-side gratings which are usually formed after removing device layers from the substrate, where but in this disclosure, gratings will be formed before forming device layers

In this disclosure, a grating is designed so as to be formed either on the host substrate or on a material placed over the substrate, thus preventing the damage of device layers during the laser lift-off.

Dielectric DBRs over the top-flat face can be formed to improve its reflectivity.

Template substrates, termed as foreign substrates, like GaN/Sapphire or GaN/Si, can be used to demonstrate gratings.

When template substrates are used, laser lift-off can be employed. In conventional scenario, template substrate usage may damage the device layers, but this disclosure using the ELO method can lower damages as the ELO mask can act as a protective layer for the device layers.

In the present disclosure, the grating on the n-side is realized with the help of designing the ELO mask. Moreover, the substrate removal has been proven for almost all of the crystal orientations of GaN substrate in the Refs. (NPL16) to (NPL20), and applying laser lift-off to foreign substrates is easily accessible. GaN substrates with high-quality and large sizes are very expensive, using the present ELO technique can unlock the usage of foreign substrates in the production of VCSELs.

Design of gratings operating at visible wavelength is tedious, complex and delicate. E-beam lithography and holography are, generally, preferred than nano-imprinting. In the nano-imprinting, the application of excess force to device layers to imprint a pattern may cause damage or breakage of the device layers. In the present disclosure, the nano-imprinting to form grating patterns is, however, carried out either on the thick host substrate or on the ELO mask, thus enabling usage of any existing technology to print the gratings.

### Formation of the Gratings

The grating surface on the n-side can be formed multiple ways including, but not limited thereto, the formation of grating patterns on the host substrate with the ELO mask. The host substrate can include a GaN-substrate, GaN/Sapphire template or GaN/Si template. The procedure of obtaining the grating is detailed in the following.
Placing a thin dielectric film of, for example, about 100 nm on the host substrate
Coating a photoresist (PR) material or nano-imprint assist material on the thin dielectric film
Transferring a grating pattern onto the material
Embedding the pattern with a dielectric material
Exposing the PR material or nano-imprint assist material by etching
Leaving a desired grating patterns on the ELO mask by removing the PR material or nano-imprint assist material

Procedures to obtain the ELO mask with a grating pattern have been presented with reference to the Drawings.

To assist semiconductor lateral growth, III nitride material underlying the ELO mask is exposed either at the openings of, for example, stripe, or any other shape.

The procedure starts with providing a host substrate, preferably GaN substrate. GaN substrates have less dislocation densities (105 to 106 defects per cm⁻²). An alternative may use template substrates, such as GaN-on-Silicon and GaN-on-Sapphire. The host substrate, such as a GaN substrate, GaN-on-Sapphire template, or GaN-on-Silicon template, is used as an ELO seed layer. Using these template substrates can improve III nitride device yield, and thus reduces production cost. Refs. (NPL15) to (NPL20) propose using the ELO method to form less-defect epitaxial layers for optical devices, such as edge emitting lasers, micro-LEDs and VCSELs.

In the first aspect of the above embodiments, a vertical cavity surface emitting laser (VCSEL) may comprise: a first distributed Bragg reflector (DBR) including a first dielectric layer and a second dielectric layer alternately arranged in a first axial direction; and a semiconductor section including a p-type III nitride region, a Ill nitride region, and a III nitride active region between the p-type III nitride region and the Ill nitride region, the p-type III nitride region, the Ill nitride active region, and the III nitride region being arranged in the first axial direction, the Ill nitride region including an n-type Ill nitride region; wherein the semiconductor section includes a monolithic grating having a periodic one-dimensional pattern, the monolithic grating, the Ill nitride active region, and the first DBR are arranged in the first axial direction to form an optical cavity, and the periodic one-dimensional pattern extends in a second axial direction that intersects the first axial direction.

In the second aspect of the embodiment, the VCSEL according to the first aspect may further comprise a dielectric layer disposed on the semiconductor section, the dielectric layer extending on the monolithic grating to cover the periodic one-dimensional pattern.

In the third aspect of the embodiment, the VCSEL according to the second aspect may further comprise a second distributed Bragg reflector, wherein the dielectric layer is disposed between the second distributed Bragg reflector and the semiconductor section, wherein the another distributed Bragg reflector includes a third dielectric layer and a fourth dielectric layer alternately arranged in the first axial direction, and wherein the second distributed Bragg reflector and the periodic one-dimensional pattern are coupled together to configure a single reflector.

In the fourth aspect of the embodiment, the VCSEL according to any one of the first to third aspects may further comprise: a conductive layer disposed on the semiconductor section, a part of the conductive layer being disposed between the first DBR and the semiconductor section; and a first electrode disposed on the conductive layer outside the first DBR, the first electrode being disposed in contact with the conductive layer.

In the fifth aspect of the embodiment, the VCSEL according to the fourth aspect may further comprise a second electrode, wherein the Ill nitride region has a first face and a second face at an opposite side from the first face, and wherein the monolithic grating is formed at the first face, and the second electrode is disposed at the second face.

In the sixth aspect of the embodiment, the VCSEL according to the fourth aspect may further comprise a second electrode, wherein the Ill nitride region has a first face and a second face at an opposite side from the first face, and wherein the monolithic grating is formed on the first face, and the second electrode is disposed on the first face.

In the seventh aspect of the embodiment, the VCSEL according to any one of the first to sixth aspects, a total cavity length of the cavity is more than 1 micrometer.

In the eighth aspect of the embodiment according to any one of the first to seventh aspects, a distance between the monolithic grating and the DBR is not more than 30 micrometers.

In the ninth aspect of the above embodiment, a method for fabricating a vertical cavity surface emitting laser (VCSEL) may comprise: forming a patterned epitaxial lateral overgrowth (ELO) mask on a face of a substrate including one of a III nitride substrate, a GaN-on-Sapphire template, or a GaN-on-Silicon template, the patterned ELO mask including a grating pattern and an opening to the face of the substrate; growing a Ill nitride on the substrate using the patterned ELO mask to form a Ill nitride region that covers the grating pattern, the grating pattern being transferred to the Ill nitride region; growing a semiconductor laminate including an n-type III nitride region, a Ill nitride active region, and a p-type III nitride region; after growing the semiconductor laminate, growing a conductive layer; forming a distributed Bragg reflector (DBR) on the conductive layer to fabricate a product, the DBR including a first dielectric layer and a second dielectric layers alternately arranged; and removing the substrate from the product to expose the patterned ELO mask, wherein the grating pattern includes a periodic one-dimensional pattern that extends along the face of the substrate.

In the tenth aspect of the above embodiment, the method according to the ninth aspect may further comprise after forming the DBR and prior to removing the substrate, forming a first metal electrode on the conductive layer.

In the 11th aspect of the above embodiment, the method according to the ninth or tenth aspect may further comprise prior to growing the semiconductor laminate, planarizing the Ill nitride region by at least one of polishing or etching.

In the 12th aspect of the above embodiment, the method according to any one of the ninth to 11th aspects may further comprise: prior to growing the conductive layer, producing a mesa from the semiconductor laminate by etching to form an etched face of the semiconductor laminate, the mesa including the III nitride active region; and forming a second electrode at the etched face of the semiconductor laminate.

In the 13th aspect of the above embodiment, the method according to any one of the ninth to 11th aspects may further comprise: after removing the substrate, removing a part of the patterned ELO mask to expose the III nitride region; and forming a second metal electrode at an exposed face of the III nitride region.

In the 14th aspect of the above embodiment, the method according to any one of the ninth to 12th aspects may further comprise, after removing the substrate, removing the patterned ELO mask.

In the 15th aspect of the above embodiment according to any one of the ninth to 13th aspects, the patterned ELO mask may further include a second DBR including a third dielectric layer and a fourth dielectric layer alternately arranged at the face of the substrate.

Having described and illustrated the principle of the invention in a preferred embodiment thereof, it is appreciated by those having skill in the art that the invention can be modified in arrangement and detail without departing from such principles. We therefore claim all modifications and variations coming within the spirit and scope of the following claims.

### REFERENCE SIGNS LIST

11,11a, 11b, 11c, 11d, 11e VCSEL
13 distributed Bragg reflector (DBR)
15 semiconductor section
17 monolithic grating
17a, 18a periodic one-dimensional pattern
17b non-patterned portion
17c patterned portion
23 p-type III-nitride region
25 n-type III nitride region
27 III nitride active region
29 optical cavity
31 anode electrode
33, 33a, 33b cathode electrode
35 conductive layer
37 mesa
LCAV total cavity length
Ax1, Ax2 axial direction

1. A vertical cavity surface emitting laser (VCSEL), comprising:
a first distributed Bragg reflector (DBR) including a first dielectric layer and a second dielectric layer alternately arranged in a first axial direction; and
a semiconductor section including a p-type III nitride region, a Ill nitride region, and a III nitride active region between the p-type Ill nitride region and the Ill nitride region, the p-type III nitride region, the Ill nitride active region, and the Ill nitride region being arranged in the first axial direction, the III nitride region including an n-type Ill nitride region,
wherein the semiconductor section includes a monolithic grating having a periodic one-dimensional pattern, the monolithic grating, the Ill nitride active region, and the first DBR are arranged in the first axial direction to form an optical cavity, and the periodic one-dimensional pattern extends in a second axial direction that intersects the first axial direction.

2. The VCSEL according to claim 1, further comprising a dielectric layer disposed on the semiconductor section, the dielectric layer extending on the monolithic grating to cover the periodic one-dimensional pattern.

3. The VCSEL according to claim 2, further comprising a second distributed Bragg reflector, (DBR) wherein:
the dielectric layer is disposed between the second DBR and the semiconductor section,
the second DBR includes a third dielectric layer and a fourth dielectric layer alternately arranged in the first axial direction, and
the second DBR and the periodic one-dimensional pattern are coupled together to configure a single reflector.

4. The VCSEL according to claim 1, further comprising:
a conductive layer disposed on the semiconductor section, a part of the conductive layer being disposed between the first DBR and the semiconductor section; and
a first electrode disposed on the conductive layer outside the DBR, the first electrode being disposed in contact with the conductive layer.

5. The VCSEL according to claim 4, further comprising a second electrode, wherein:
the Ill nitride region has a first face, and a second face at an opposite side from the first face, and
the monolithic grating is formed at the first face, and the second electrode is disposed at the second face.

6. The VCSEL according to claim 4, further comprising a second electrode, wherein:
the Ill nitride region has a first face, and a second face at an opposite side from the first face, and
the monolithic grating is formed at the first face, and the second electrode is disposed at the first face.

7. The VCSEL according to claim 1, wherein a total cavity length of the cavity is more than 1 micrometer.

8. The VCSEL according to claim 1, wherein a distance between the monolithic grating and the DBR is not more than 30 micrometers.

9. A method for fabricating a vertical cavity surface emitting laser (VCSEL), the method comprising:
forming a patterned epitaxial lateral overgrowth (ELO) mask on a face of a substrate including one of a Ill nitride substrate, a silicon substrate, a sapphire substrate, a GaN-on-Sapphire template, or a GaN-on-Silicon template, the patterned ELO mask including a grating pattern and an opening to the face of the substrate;
growing a Ill nitride on the substrate using the patterned ELO mask to form a Ill nitride region that covers the grating pattern, the grating pattern being transferred to the III nitride region;
growing a semiconductor laminate including an n-type III nitride region, a Ill nitride active region, and a p-type III nitride region;
after growing the semiconductor laminate, growing a conductive layer;
forming a first distributed Bragg reflector (DBR) on the conductive layer to fabricate a product, the first DBR including a first dielectric layer and a second dielectric layer alternately arranged; and
removing the substrate from the product to expose the patterned ELO mask;
wherein the grating pattern includes a periodic one-dimensional pattern that extends along the face of the substrate.

10. The method according to claim 9, further comprising, after forming the first DBR and prior to removing the substrate, forming a first metal electrode at the conductive layer.

11. The method according to claim 9, further comprising, prior to growing the semiconductor laminate, planarizing the III nitride region by at least one of polishing or etching.

12. The method according to claim 9, further comprising:
prior to growing the conductive layer, producing a mesa from the semiconductor laminate by etching to form an etched face of the semiconductor laminate, the mesa including the Ill nitride active region; and
forming a second electrode at the etched face of the semiconductor laminate.

13. The method according to claim 9, further comprising:
after removing the substrate, removing a part of the patterned ELO mask to expose the III nitride region; and
forming a second metal electrode at an exposed face of the III nitride region.

14. The method according to claim 9, further comprising, after removing the substrate, removing the patterned ELO mask.

15. The method according to claim 9, wherein the patterned ELO mask further includes a second distributed Bragg reflector including a third dielectric layer and a fourth dielectric layer alternately arranged at the face of the substrate.
